(19) United States
(12) Patent Application Publication
(10) Pub. No.: US 2026/0266875 A1
(43) Pub. Date: Sep. 10, 2026

(54) METHOD OF MANUFACTURING MULTILAYER PCB FOR SEMICONDUCTOR TESTING, MULTILAYER PCB MANUFACTURED THEREBY, AND SEMICONDUCTOR TEST SOCKET USING THE SAME AND ASSEMBLY THEREOF

(71) Applicants: Young Dae KIM, Seongnam-si (KR); TES CO., LTD, Yongin-si (KR)

(72) Inventor: Young Dae KIM, Seongnam-si (KR)

(73) Assignees: Young Dae KIM, Seongnam-si (KR); TES CO., LTD, Yongin-si (KR)

(21) Appl. No.: 19/555,963

(22) Filed: Mar. 4, 2026

(30) Foreign Application Priority Data
Mar. 5, 2025 (KR) 10-2025-0028424

(51) Int. Cl. G01R 3/00; G01R 1/04

(52) U.S. Cl. CPC G01R 3/00; G01R 1/0441

(57) ABSTRACT

A method of manufacturing a multilayer PCB for semiconductor testing includes an operation (a) of preparing a copper clad laminate (CCL) plate, an operation (b) of forming a fine pad to be used for a fine pillar for replacing a plated through hole (PTH) in the CCL plate, an operation (c) of, in a state in which copper foils are laminated on upper and lower layers of the CCL plate with prepreg interposed therebetween, etching the copper foils, an operation (d) of forming chemical copper on the copper foils of an intermediate product subjected to the operation (c), an operation (e) of forming electrolytic copper in a state in which a photo resist image is formed using a dry film and forming the fine pillar in the fine hole, an operation (f) of forming a circuit pattern, and an operation (g) of repeatedly performing the operations (c) to (f).

### CROSS-REFERENCE TO RELATED APPLICATION(S)

This application claims priority to and the benefit of Korean Patent Application No. 10-2025-0028424, filed on March 5, 2025, the disclosure of which is incorporated herein by reference in its entirety.

### BACKGROUND

### Field

The present invention relates to a method of manufacturing a multilayer printed circuit board (PCB) for semiconductor testing, and more particularly, to a method of manufacturing a multilayer PCB for semiconductor testing by which an ultra-fine circuit pitch is implemented on the multilayer PCB for semiconductor testing while a thickness of the multilayer PCB may be appropriately adjusted to be compatible with an existing PCB, a multilayer PCB manufactured thereby, and a semiconductor test socket using the same and an assembly thereof.

### Description of Related Art

As is well known, semiconductor processes are largely divided into a fabrication (Fab) process of performing fabrication using a wafer and a package process of packaging a chip formed on the wafer. After the two processes are performed, it is necessary to determine whether each of the chips is defective, and thus a test process is required for this purpose.

Meanwhile, a pitch of a printed circuit board (PCB) for semiconductor testing may be determined according to a spacing of wafer chip bonding pads in the case of wafer electric die sorting (EDS), and for example, determined according to a spacing between balls of a ball grid array (BGA) (various types of semiconductor packages other than the BGA may exist) in the case of package testing.

In the case of the PCB for semiconductor package testing, a BGA ball pitch mainly ranges from 0.3 to 1.27 mm, and a test socket used therefor also has substantially the same pitch.

When describing an existing PCB for semiconductor packaging compared to the PCB for semiconductor package testing, the existing PCB used for semiconductor packaging (generally in this case, referred to as a substrate instead of a PCB) has a thickness of 0.2 to 0.3 mm or less which is very thin, and the number of layers thereof is mainly two, and four layers are used only in a special case.

As a material of the substrate, instead of a flame retardant 4 (FR4) material used for a PCB of a general home appliance or electronic device, a bismaleimide triazine (BT) material, which has good heat resistance, has excellent bonding strength with a molding material during package manufacturing, and has excellent quality and reliability as a semiconductor package, is mainly used. On the other hand, for the PCB for semiconductor package testing, unlike the above-described substrate, FR4, high glass transition temperature FR4 (High Tg FR4), and polyimide materials are mainly used.

Meanwhile, the semiconductor package test processes may be broadly classified into a room temperature test process performed at room temperature and a burn-in test process performed at a high temperature of 125 °C or higher. Here, the burn-in test process is for testing semiconductor products under a severe condition of high temperature during production so as to remove the semiconductor products having imperfect quality in advance.

Since the burn-in test process is performed inside a high-temperature chamber in a state in which semiconductor packages are individually inserted into a burn-in board (PCB) into which a plurality of burn-in sockets are inserted, a general FR4 material having a low glass transition temperature (Tg) are not used as a material of a test PCB, and thus polyimide, BT, and High Tg FR4 materials having a high Tg are used.

Meanwhile, when describing a process of manufacturing a general PCB including the PCB for semiconductor package testing and the substrate for semiconductor packaging, in the case of the general PCB, since lines defining pattern widths of a PCB circuit and spaces defining spacings between the lines are relatively wide, the general PCB is mainly manufactured by a tenting method or a subtractive method that is a long-established conventional method.

On the other hand, the substrate for semiconductor packaging is mainly manufactured by a modified semi additive process (mSAP) or a semi additive process (SAP) because PCB lines and spaces are extremely ultra-fine compared with the above-described general PCB. The SAP process is a process for manufacturing a PCB having lines and spaces that are finer and narrower compared to the mSAP process, and the line and the space are approximately 60 µm or more in the tenting method, 40 to 60 µm in the mSAP method, and 40 µm or less in the SAP method. In a method according to the present invention, the mSAP method and the SAP method may be used, and hereinafter, a description will be provided by taking the mSAP method as an example.

Meanwhile, unlike the general PCB and the substrate for semiconductor packaging, since the PCB for semiconductor package testing requires socket pins of test sockets and connector pins to be inserted into all layers of the PCB, the PCB includes plated through holes (PTHs), has an increased thickness, and is implemented as a multilayer PCB having four to eight or more layers. Further, with the trend toward thinner, lighter, and smaller semiconductor packages, in recent years, there has been a recent demand for a PCB for package testing that has a line width and a space width of 60 µm or less, a PTH diameter of 0.125 to 0.127 mm, and a spacing between the PTHs of 0.25 to 0.30 mm. Hereinafter, the line width, the space width, and the spacing between holes, such as the PTHs, of the PCB are collectively referred to as a “circuit pitch.”

Depending on a type of a semiconductor package, a test environment, and other conditions, the semiconductor package burn-in test processes may be broadly classified into a direct test method in which a package is directly inserted into a test socket SC soldered to a main board and tested, and a device-under-test (DUT) board method in which a test socket assembly is manufactured and inserted into a main board connector hole, and hereinafter, a description will be provided by taking the DUT board method as an example.

FIG. 1 is a photograph showing an actual main board for semiconductor package testing using the DUT board method, and FIGS. 2A and 2B are a front perspective photograph and a rear perspective photograph, respectively, of a test socket assembly inserted into each DUT slot of the main board shown in FIG. 1.

As shown in FIG. 1, the main board for semiconductor package testing using the DUT board method may be formed of a PCB having, for example, a size of 450 mm×570 mm and a thickness of 1.2 to 2.4 mm or a size of 450 mm×550 mm and a thickness of 1.2 to 2.4 mm. On the surface of the main board, DUT slots into which a plurality of test socket assemblies as shown in FIGS. 2A and 2B are inserted are arranged at intervals in a matrix form.

The test socket assembly includes a DUT board DB formed of the PCB for semiconductor package testing and a test socket SC soldered to the DUT board DB and into which a DUT (not shown) is inserted. The DUT board may be formed of a PCB having, for example, a size of 10 mm×11 mm and a thickness of 1.2 mm, a size of 20 mm×22 mm and a thickness of 1.6 mm, a size of 20 mm×25 mm and a thickness of 2.0 mm, or a size of 30 mm×33 mm and a thickness of 1.2 mm, and a plurality of connector pins (see FIG. 2B) coupled to connector holes of the main board may be arranged side by side on lower surfaces of both sides of an insertion portion of the test socket SC.

The main board for semiconductor package testing using the DUT board method has the advantage of convenience in that even when a type of a semiconductor package, which is a DUT to be tested, is changed, the main board may be left in place and only the test socket assembly may be replaced, which is convenient, and also has the advantage of easy maintenance and management since the test socket assembly is not directly soldered to the main board.

FIG. 3 is a partial cross-sectional configuration view according to an example of a multilayer PCB constituting a conventional DUT board for semiconductor package testing. As shown in FIG. 3, in the multilayer PCB constituting the conventional DUT board for semiconductor package testing, a plated through hole PTH, a non-plated through hole NPTH, or the like vertically passing through an entirety of the multilayer PCB with an inside thereof plated or non-plated may be present, and in addition thereto, various types of holes (blind vias and buried vias) formed to pass through only some layers of the multilayer PCB may be present.

FIG. 4 is a partial cross-sectional configuration view according to an example of an eight-layer PCB constituting a conventional DUT board for semiconductor package testing and shows the eight-layer PCB manufactured by a tenting method. As shown in FIG. 4, in the conventional DUT board for semiconductor package testing manufactured by the tenting method, with an insulating layer, for example, a core layer Core or a prepreg layer Prepreg, interposed between layers, signal layers Signal may be disposed on a first layer and a second layer, and a ground layer GND and a signal layer may be disposed on a third layer and a fourth layer, respectively. A power layer Power and a signal layer may be disposed on a fifth layer and a sixth layer, and a power layer and a signal layer may be disposed on a seventh layer and an eighth layer.

In the above-described configuration, the fourth layer and the fifth layer, which are intermediate layers, may be implemented as a copper clad laminate (CCL), and this CCL may be provided in advance in a state in which copper foils are laminated on upper and lower surfaces of the core layer, which is the insulating layer. In addition, the second and third layers and the sixth and seventh layers may also be implemented as a CCL provided in advance. First, copper foils of the second layer and the third layer, the fourth layer and the fifth layer, and the sixth layer and the seventh layer, which are manufactured and provided in advance in a CCL form, are appropriately patterned (to be described below) according to a purpose of each layer to form a signal layer, a power layer, and a ground layer.

In this state, prepreg is interposed between the third layer CCL and the fourth layer CCL, prepreg is interposed between the fifth layer CCL and the sixth layer CCL, and prepreg and copper foil are interposed on an upper surface of the second layer and a lower surface of the seventh layer, and then first to eighth layers are simultaneously bonded. Thereafter, signal layers of the first layer and the eighth layer may be completely formed by forming a PTH, forming chemical copper and electrolytic copper, and then performing patterning, and after a photo imageable solder resist (PSR) process for protecting a signal pattern is performed, silk printing, gold plating, and routing processes may be performed, thereby manufacturing the DUT board for semiconductor package testing.

Meanwhile, in the DUT board for semiconductor package testing manufactured as described above, a thickness of the DUT board may be appropriately adjusted by appropriately increasing or decreasing a thickness of a core layer constituting each CCL or copper foils laminated on upper and lower surfaces thereof.

FIG. 5 is a process flowchart for describing a method of manufacturing a conventional DUT board for semiconductor package testing using a tenting method. As shown in FIG. 5, in the conventional DUT board for semiconductor package testing using the tenting method, for example, for a first layer, after a hole is formed in a prepreg and copper foil layers laminated on an upper portion of a second layer, in a state in which a chemical copper layer functioning as a seed is thinly formed by an electroless plating method, an electrolytic copper layer having a desired thickness is formed thereon by an electroplating method. In this state, after a photo image is formed using a dry film on the electrolytic copper layer, a desired pattern may be formed in the copper foil and electrolytic copper layers through development–etching–stripping processes, thereby completing a circuit pattern for the first layer.

Since the copper foil is already laminated in the respective CCLs constituting the second layer and the third layer, the fourth layer and the fifth layer, and the sixth layer and the seventh layer, the circuit pattern for the corresponding layer may be completely formed starting from a process of forming a photo image using a dry film.

FIGS. 6A and 6B are a photograph and a cross-sectional view, respectively, showing a circuit pattern formed by the method of manufacturing a conventional DUT board for semiconductor package testing using the tenting method. FIG. 7 is a view for describing problems of the conventional DUT board for semiconductor package testing manufactured using the tenting method. As shown in FIG. 6, in the conventional DUT board for semiconductor package testing manufactured using the tenting method, since a signal line pattern has a substantially trapezoidal shape having a thicker bottom and a thinner top due to an undercut during etching, there is a limitation in reducing a pitch of a line or a space to 60 µm or less. Accordingly, when an ultra-fine circuit pattern of 60 µm or less is required, as illustrated in FIG. 7, since a width of a signal line SL is greater than a spacing between PTHs, the signal line may not be disposed between the PTHs, and as a result, there is a problem in that a multilayer PCB for semiconductor package testing having an ultra-fine circuit pattern may not be provided.

Examples of related art include Korean Laid-Open Patent Publication No. 10-1998-0022345 (Title of the Invention: Printed Circuit Board for Manufacturing BGA Semiconductor Package Capable of Electrical Testing), Korean Laid-Open Patent Publication No. 10-2023-0038559 (Title of the Invention: Method for Manufacturing Package Substrate), and Korean Laid-Open Patent Publication No. 10-2017-0132628 (Title of the Invention: Semiconductor Package Test Socket).

### SUMMARY

The present invention has been devised to solve the above-described problems, and an object thereof is to provide a method of manufacturing a multilayer printed circuit board (PCB) for semiconductor testing by which an ultra-fine circuit pattern is implemented in the multilayer PCB for semiconductor testing while a thickness of the multilayer PCB may be appropriately adjusted to be compatible with an existing PCB, a multilayer PCB manufactured thereby, and a semiconductor test socket using the same and an assembly thereof.

Another object of the present invention is to provide a method of manufacturing a multilayer PCB configured to electrically connect the multilayer PCB in a vertical direction using fine pillars having a diameter smaller than that of a plated through hole (PTH) instead of of the PTH, a multilayer PCB manufactured thereby, and a semiconductor test socket using the same and an assembly thereof.

In order to achieve the above-described object, according to one aspect of the present invention, a method of manufacturing a multilayer PCB for semiconductor testing includes an operation (a) of preparing a copper clad laminate (CCL) plate of which copper foil layers serving as dummy layers are formed on both surfaces of a core layer, an operation (b) of forming a fine pad to be used for a fine pillar for replacing a PTH in the CCL plate, an operation (c) of, in a state in which copper foils are laminated on upper and lower layers of the CCL plate with prepreg interposed therebetween, etching the copper foils to reduce a thickness thereof and then forming a fine hole, an operation (d) of forming chemical copper on the copper foils of an intermediate product subjected to the operation (c), an operation (e) of forming electrolytic copper in a state in which a photo resist image is formed using a dry film and forming the fine pillar in the fine hole during the forming of the electrolytic copper, an operation (f) of forming a circuit pattern by removing the chemical copper and the remaining portions of the copper foils by etching after stripping the dry film, and an operation (g) of repeatedly performing the operations (c) to (f) until all layers are completely formed.

In the above-described configuration, the fine pad formed in the operation (b) may be formed by forming the fine hole in the CCL plate, copper-plating a wall surface of the fine hole, filling the copper-plated fine hole with a filler of a resin material, and then performing copper plating.

The number of dummy layers may be two or more.

A thickness of a core of the dummy layer may be adjusted to be compatible with an existing multilayer PCB.

The multilayer PCB may be a multilayer PCB for semiconductor package testing.

The multilayer PCB may be a PCB for a device-under-test (DUT) board or a PCB for a main board.

According to another aspect of the present invention, a PCB for semiconductor testing manufactured by the above-described method is provided.

According to still another aspect of the present invention, there is provided a semiconductor test socket assembly including the above-described PCB for semiconductor testing and a test socket including socket pins soldered in a state in which each socket pint is in surface contact with a corresponding one of a plurality of fine pillars exposed on an uppermost layer of the PCB for semiconductor testing and a plurality of dummy pins supported by the PCB for semiconductor testing by vertically passing through the PCB for semiconductor testing.

According to yet another aspect of the present invention, there is provided a semiconductor test socket including socket pins soldered in a state in which each socket pint is in surface contact with a corresponding one of a plurality of fine pillars exposed on an uppermost layer of the above-described PCB for semiconductor testing and a plurality of dummy pins supported by the PCB for semiconductor testing by vertically passing through the PCB for semiconductor testing.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a photograph showing an actual main board for semiconductor package testing using a device under test (DUT) board method;

FIGS. 2A and 2B are a front perspective photograph and a rear perspective photograph, respectively, of a test socket assembly inserted into each DUT slot of a main board;

FIG. 3 is a partial cross-sectional configuration view according to an example of a multilayer printed circuit board (PCB) constituting a conventional DUT board for semiconductor package testing;

FIG. 4 is a partial cross-sectional configuration view according to an example of an eight-layer PCB constituting a conventional DUT board for semiconductor package testing;

FIG. 5 is a process flowchart for describing a method of manufacturing a DUT board for semiconductor package testing using a conventional tenting method;

FIGS. 6A and 6B are a photograph and a cross-sectional view, respectively, showing a circuit pattern formed by a method of manufacturing a DUT board for semiconductor package testing using a conventional tenting method;

FIG. 7 is a view for describing problems of a DUT board for semiconductor package testing manufactured using a conventional tenting method;

FIG. 8 is a process flowchart for describing a modified semi additive process (mSAP) method applicable to manufacturing a multilayer PCB for semiconductor testing of the present invention;

FIGS. 9A and 9B are a photograph and a cross-sectional view, respectively, showing a circuit pattern formed by a method of manufacturing a DUT board for semiconductor package testing using an mSAP method;

FIG. 10 is a process flowchart for describing a method of manufacturing a DUT board for semiconductor package testing according to one embodiment of the present invention;

FIG. 11 is a schematic longitudinal cross-sectional view of a part of a multilayer PCB manufactured according to the embodiment of FIG. 10;

FIG. 12A is a transverse cross-sectional view showing a region around a fine pillar of a multilayer PCB manufactured according to the embodiment of FIG. 10, and FIG. 12B is a transverse cross-sectional view showing a region around a fine pillar of a multilayer PCB manufactured according to another embodiment of the present invention;

FIG. 13 is a schematic cross-sectional view for describing a thickness ratio of a dummy layer and the remaining layers in a multilayer PCB manufactured by the method of manufacturing a multilayer PCB for semiconductor testing of the present invention;

FIGS. 14A and 14B are schematic longitudinal cross-sectional views of test sockets applied to multilayer PCBs manufactured by a conventional method and by a method of the present invention, respectively; and

FIGS. 15A and 15B are schematic longitudinal cross-sectional views of test socket assemblies to which the test sockets shown in FIGS. 14A and 14B are applied, respectively.

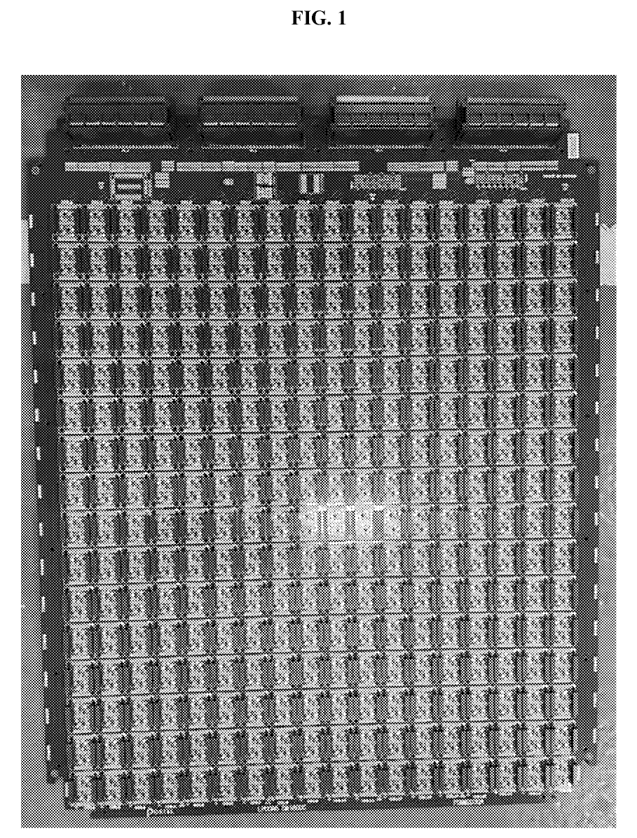

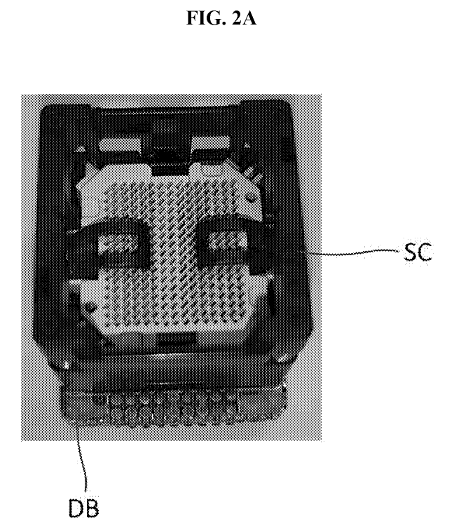

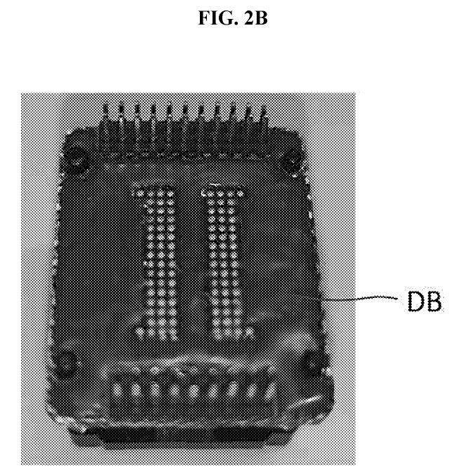

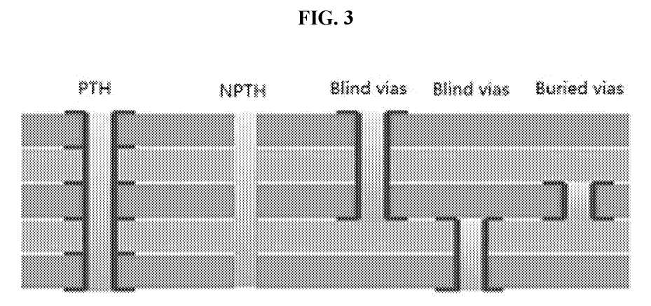

### DETAILED DESCRIPTION

Below, exemplary embodiments of a method of manufacturing a multilayer printed circuit board (PCB) for semiconductor testing of the present invention, a multilayer PCB manufactured thereby, and a semiconductor test socket using the same and an assembly thereof will be described in detail with reference to the accompanying drawings, and detailed descriptions of known functions and configurations that may unnecessarily obscure the gist of the invention are omitted. Further, since embodiments of the present invention are provided to more completely describe the present invention to a person having ordinary skill in the art, shapes, sizes, and the like of elements in the drawings may be exaggerated for clearer description.

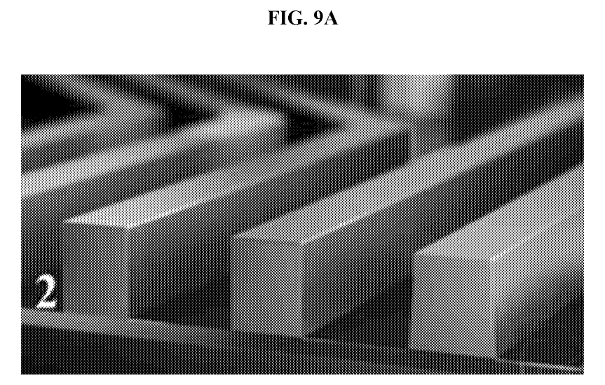

FIG. 8 is a process flowchart for describing a modified semi additive process (mSAP) method applicable to manufacturing the multilayer PCB for semiconductor package testing of the present invention. As shown in FIG. 8, according to the mSAP method applicable to manufacturing the multilayer PCB for semiconductor package testing of the present invention, first, in a state in which a chemical copper layer functioning as a seed is thinly formed on copper foil on a core layer by an electroless plating method, a photo resist is formed using a dry film, and then an electrolytic copper layer to be a circuit pattern is formed again by an electroplating method, thereby forming the electrolytic copper layer only on an upper portion of chemical copper in a portion in which the pohto resist is not present.

Next, after the dry film used as the photo resist is stripped, rapid etching is performed by a flash etching method to remove the chemical copper present under the photo resist and a copper foil layer remaining thereunder, thereby completing an ultra-fine circuit having a pitch of 40 to 60 µm.

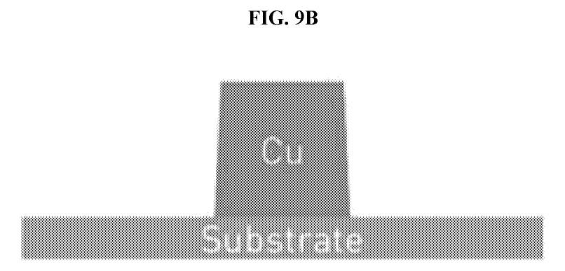

FIGS. 9A and 9B are a photograph and a cross-sectional view, respectively, showing a circuit pattern formed by a method of manufacturing a DUT board for semiconductor package testing using the mSAP method. As shown in FIG. 9, in the DUT board for semiconductor package testing manufactured by the mSAP method, a relatively sharp square-shaped signal line pattern may be formed by rapid etching using a flash etching method as compared with a tenting method, and as a result, a pitch of a line or a space may be reduced to 40 to 60 µm or less.

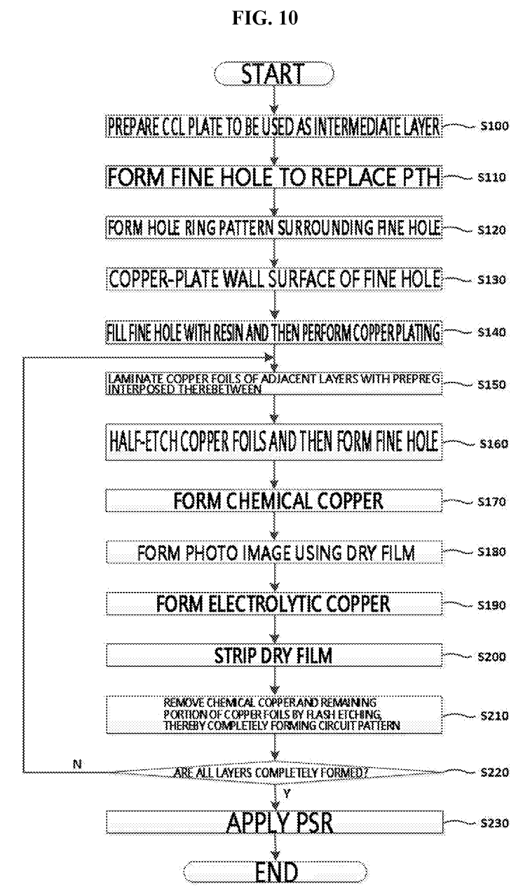

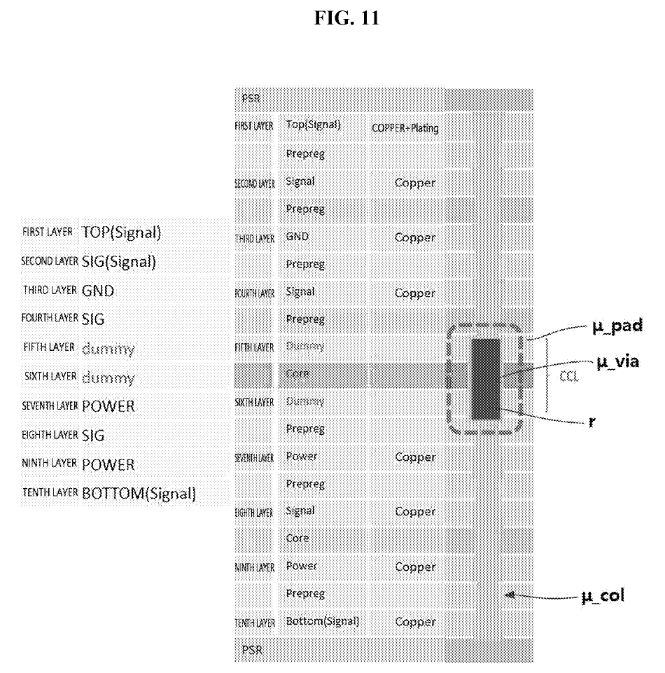

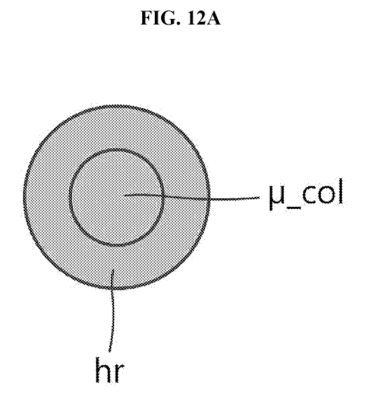

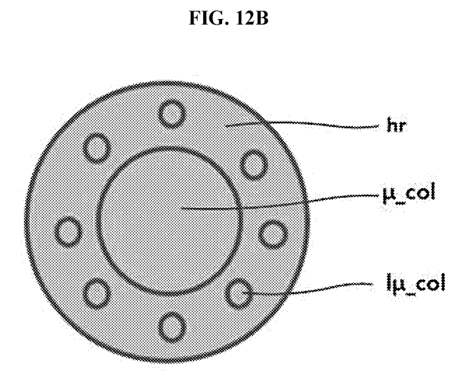

FIG. 10 is a process flowchart for describing a method of manufacturing a DUT board for semiconductor package testing according to one embodiment of the present invention. FIG. 11 is a schematic longitudinal cross-sectional view of a part of a multilayer PCB manufactured according to the embodiment of FIG. 10. FIG. 12A is a transverse cross-sectional view showing a region around a fine pillar of the multilayer PCB manufactured according to the embodiment of FIG. 10, and FIG. 12B is a transverse cross-sectional view showing a region around a fine pillar of a multilayer PCB manufactured according to another embodiment of the present invention.

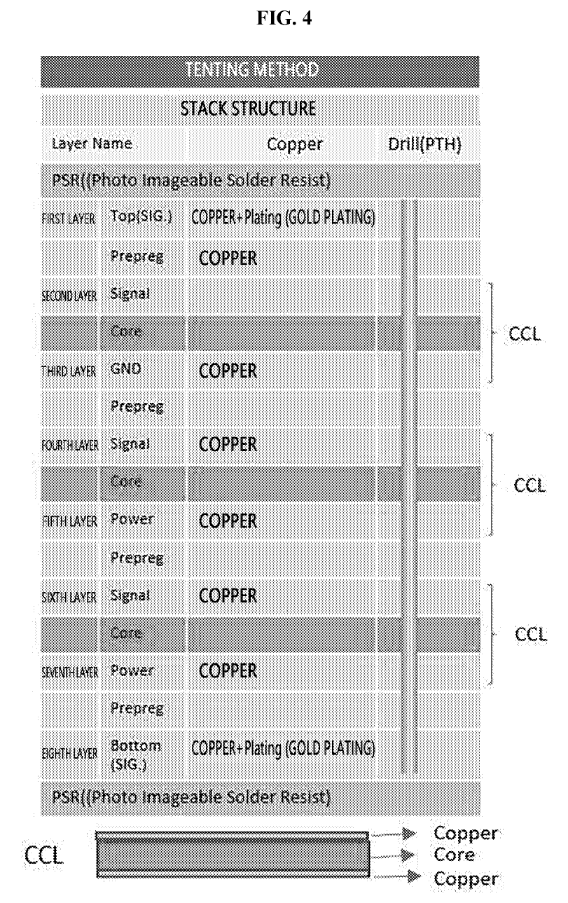

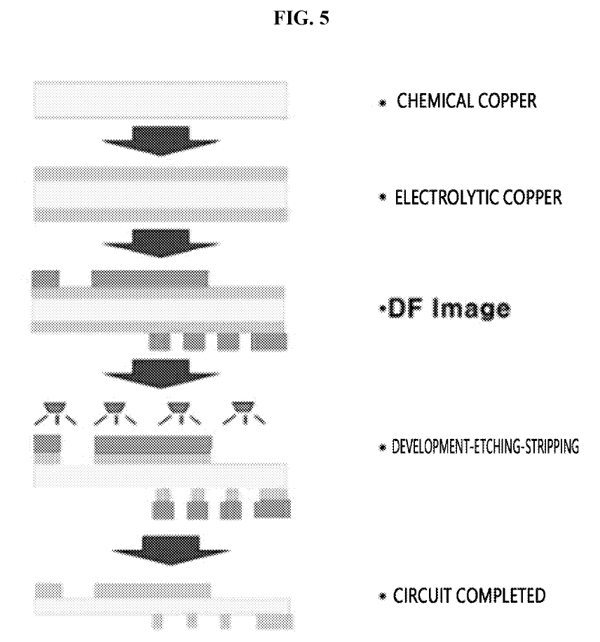

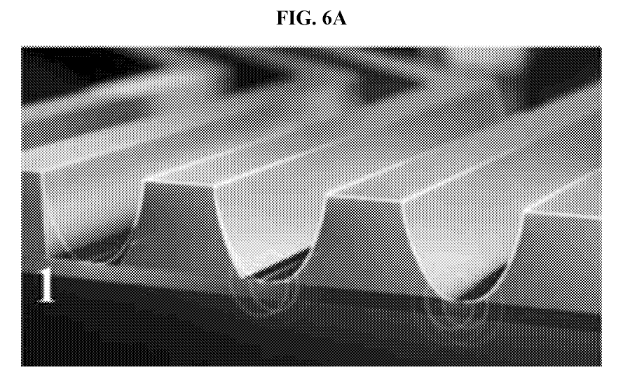

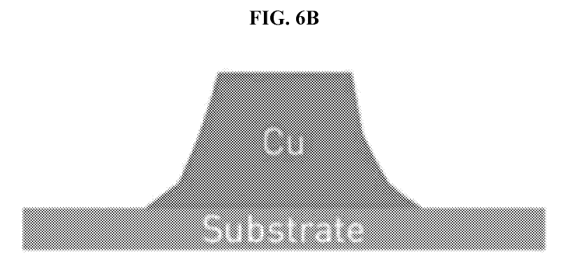

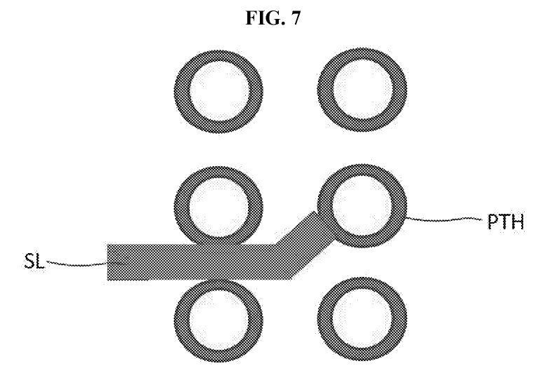

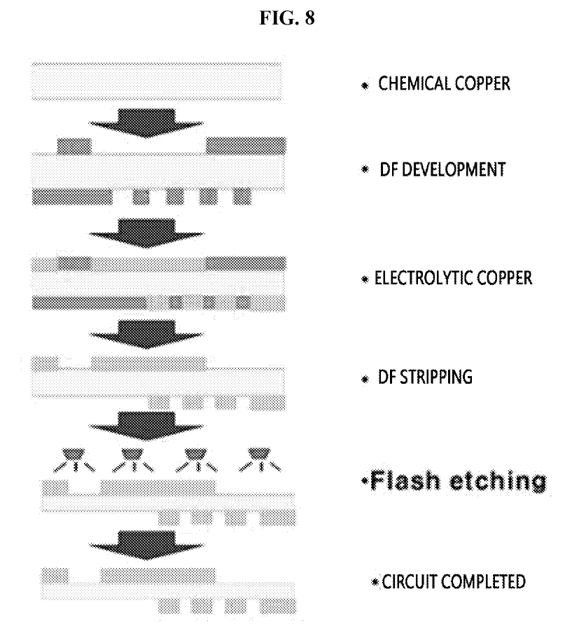

First, in FIG. 11, a PCB having a total of ten layers in which a fifth layer and a sixth layer functioning as dummy layers are additionally inserted below a fourth layer of the eight-layer PCB shown in FIG. 4 is illustrated.

In addition, similar to the eight-layer PCB shown in FIG. 4, in a state in which an insulating layer, for example, a core layer or a prepreg layer, is interposed between layers, signal layers may be disposed on a first layer and a second layer and a ground layer GND and a signal layer may be disposed on a third layer and a fourth layer, respectively. However, unlike the eight-layer PCB shown in FIG. 4, in a fifth layer and a sixth layer of the PCB manufactured by the method of the present invention, dummy layers formed of copper foil layers are disposed with the core layer interposed therebetween. Accordingly, a power layer and a signal layer may be disposed on a seventh layer and an eighth layer, and a power layer and a signal layer may be disposed on a ninth layer and a tenth layer.

In the above-described configuration, the fifth layer and the sixth layer, which are dummy layers, may be provided in advance as being implemented as a CCL. Further, by appropriately adjusting a thickness of the core layer of the CCL, a thickness of the ten-layer PCB manufactured by the method of the present invention may be made the same as a thickness of the eight-layer PCB shown in FIG. 4, and accordingly, existing semiconductor package test equipment may be used without any change. Of course, in addition to the core layer, by adjusting a thickness of copper foil layers of the fifth layer and the sixth layer provided as dummy layers together with the thickness of the core layer, an overall thickness of the ten-layer PCB may be made the same as the thickness of the eight-layer PCB shown in FIG. 4.

In addition, referring to such a method of manufacturing a multilayer PCB, in operation S100 of FIG. 10, a CCL plate to be used as an intermediate layer, that is, a CCL plate manufactured by laminating copper foil layers to function as dummy layers on both surfaces of a core layer, for example, the fifth layer and the sixth layer in FIG. 11, may be prepared, and this prepared CCL plate may be manufactured to have a desired thickness by adjusting a thickness of the core layer or the copper foil layers.

Next, in operation S110, for example, by a drilling process (or a laser processing process), a fine hole μ_via to be used for a fine pillar μ_col for replacing a conventional PTH, for example, a fine hole μ_via having a diameter range of 10 to 150 µm, is formed, and in a subsequent operation S120, a hole ring pattern hr (see FIG. 12A) surrounding the fine hole is formed.

In contrast, as shown in FIG. 12B, in order to improve heat dissipation performance, in the process of forming the fine hole μ_via in operation S110, a plurality of ultra-fine holes lμ_via having a diameter smaller than that of the fine hole μ_via may be further formed around the fine hole μ_via. Since the ultra-fine pillar formed through such ultra-fine holes lμ_via is formed through the same operations as the fine pillar μ_col described below, detailed descriptions thereof are omitted.

Next, in operation S130, a wall surface of the fine hole μ_via is copper-plated, and in a subsequent operation S140, the copper-plated fine hole μ_via is filled with a filler r of a resin material and then copper-plated to form a fine pad μ_pad.

Next, in operation S150, in a state in which copper foils are laminated on upper and lower layers of the CCL plate with prepreg interposed therebetween, bonding is performed by a hot press method, and in a subsequent operation S160, the copper foil layers are etched again to appropriately reduce a thickness thereof, for example, to about half, and in this state, the fine hole μ_via is formed in alignment with the fine pad μ_pad formed in the previous operation S140, for example, by a laser processing process (or a drilling process).

Next, in operation S170, chemical copper is formed on the copper foil layers of the intermediate product manufactured as described above.

Next, in operation S180, a photo resist image is formed using a dry film, and in a subsequent operation S190, electrolytic copper is formed on the intermediate product subjected to operation S180, and thus electrolytic copper is formed only on the portion of the chemical copper where the photo resist formed in operation S180 is not present, and in this process, the fine pillar μ_col is formed in the fine hole μ_via formed in operation S160.

Next, in operation S200, the dry film is stripped, and in a subsequent operation S210, chemical copper and copper foil portions remaining thereunder are rapidly etched and removed by flash etching, thereby forming an ultra-fine circuit pattern having a pitch of 40 to 60 µm. Next, in operation S220, whether all layers (for example, a total of ten layers in FIG. 11) are completely formed is determined, and when not all layers are completely formed, operations S150 and subsequent operations are repeatedly performed on the intermediate product progressed so far, and when all layers are completely formed, the process proceeds to operation S230 to apply a photo imageable solder resist (PSR) and end the process.

As described above, according to the method of manufacturing a multilayer PCB for semiconductor package testing of the present invention, by using the CCL plate as the dummy layer to appropriately adjust the thickness thereof, thickness compatibility with an existing multilayer PCB may be achieved, and in addition, by performing patterning for the remaining layers by the mSAP method in place of a conventional tenting method, the circuit pitch of a signal layer, a ground layer, and a power layer may be reduced, for example, to 60 µm or less. Further, the fine pillars μ_col have an effect of solving thermal problems emerging as a semiconductor becomes faster, more complex, and highly functional.

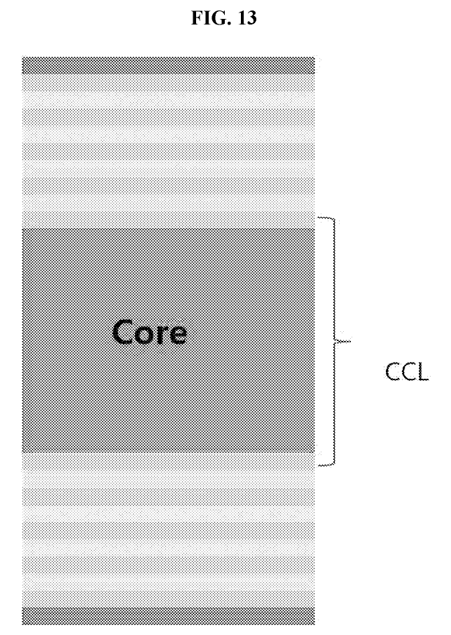

FIG. 13 is a schematic cross-sectional view for describing a thickness ratio between a dummy layer and the remaining layers in a multilayer PCB manufactured by the method of manufacturing a multilayer PCB for semiconductor testing of the present invention, and a description will be provided by taking the multilayer PCB shown in FIG. 11 as an example. As shown in FIG. 13, a thickness of a core layer interposed between dummy layers of a fifth layer and a sixth layer may be determined to be approximately between 40% and 60% compared with a thickness of each of the remaining layers.

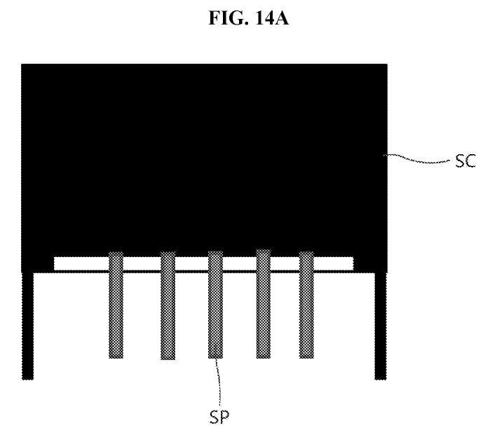

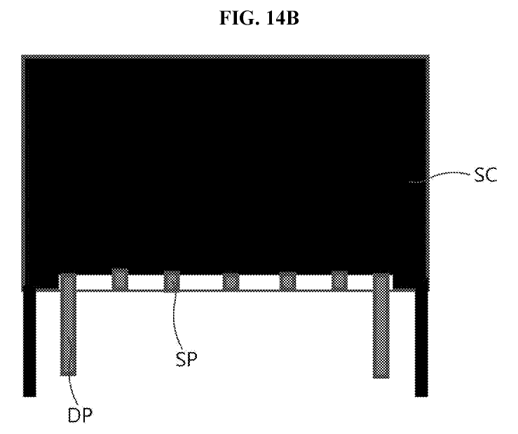

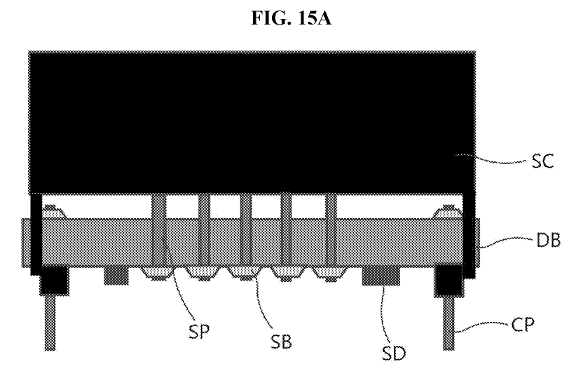

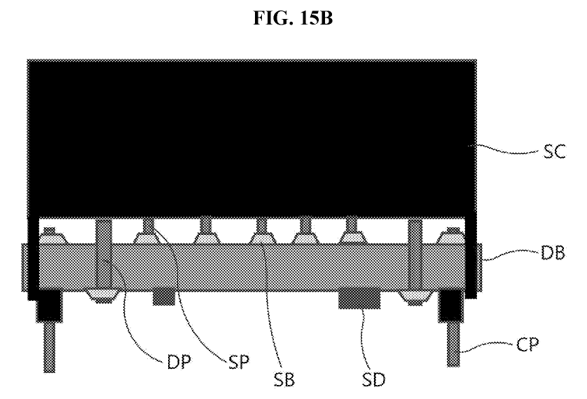

FIGS. 14A and 14B are schematic longitudinal cross-sectional views of test sockets applied to multilayer PCBs manufactured by a conventional method and by the method of the present invention, respectively, FIGS. 15A and 15B are schematic longitudinal cross-sectional views of test socket assemblies to which the test sockets shown in FIGS. 14A and 14B are applied, respectively, wherein reference sign SC denotes a test socket, DB denotes a DUT board, and CP denotes a connector pin inserted into a main board.

SP denotes a socket pin, SB denotes a soldering portion, and SD denotes a semiconductor device (such as a passive device). DP denotes a dummy pin for firmly fixing a test socket SC to a DUT board DB, and such dummy pins DP may be provided one at each edge of the DUT board (DB), thereby providing a total of four or more dummy pins.

According to the method of manufacturing a multilayer PCB for semiconductor testing of the present invention, since the fine pillars μ_col are formed in place of the PTH of the multilayer PCB DB through which the socket pin SP of the conventional test socket SC passes, the socket pin SP of the test socket SC may be electrically connected to the fine pillars μ_col exposed on an uppermost layer of the multilayer PCB DB by a surface mount technology (SMT) method.

As a result, a length of the socket pin SP may be decreased as compared with a conventional socket pin pass-through method, thereby reducing alignment precision deterioration due to bending of the socket pin SP or the like during insertion of the socket pin SP into a PTH of a conventional socket pin SP, and by preventing short circuits between a soldering portion of the socket pin SP, connection defects or lifting inside the PTH, stripping, and fine cracks, productivity, quality, and reliability can be improved and manufacturing cost can be reduced.

Further, by electrically connecting upper and lower layers of the multilayer PCB by the fine pillars μ_col in a pillar form in place of the PTH formed in a hole form, a heat dissipation effect may be enhanced.

The method of manufacturing a multilayer PCB for semiconductor testing of the present invention, the multilayer PCB manufactured thereby, and the test socket used therein are not limited to the above-described embodiments and may be variously modified and implemented within a scope permitted by the technical idea of the present invention. Therefore, a true scope of protection of the present invention should be determined only by the appended claims.

That is, in the above-described embodiments, the multilayer PCB for semiconductor package testing has been described as an example, but the present invention is not limited thereto and may also be applicable to a wafer electric die sorting (EDS) test.

Further, the multilayer PCB for semiconductor testing of the present invention is formed of an even number of layers of four layers or more, and a use of each layer will appropriately change depending on a use of the corresponding semiconductor.

In addition, unlike the above-described embodiments, the method of manufacturing a multilayer PCB of the present invention may be applicable not only to a DUT board but also to a main board to which a test socket assembly is directly soldered.

Further, by using the conventional tenting method, an appropriate circuit pattern may also be formed on the dummy layer, and when necessary for thickness adjustment and the like, more than two dummy layers may be formed.

Further, in the above-described embodiments, the multilayer PCB of the present invention has been described as being manufactured by the mSAP method, but the multilayer PCB of the present invention may also be manufactured by the SAP method.

According to a method of manufacturing a PCB for semiconductor testing according to the present invention, a multilayer PCB can be implemented using an mSAP method for a signal layer and the like requiring an ultra-fine circuit pitch, and a thickness thereof can be adjusted through a dummy layer implemented using a conventional tenting method, thereby enabling thickness compatibility with an existing PCB for semiconductor testing.

Further, since fine pillars are formed to replace PTHs of a multilayer PCB through which socket pins of a conventional test socket pass, the socket pins of the test socket can be electrically connected to fine pillars exposed on an uppermost layer of the multilayer PCB by a surface mount technology (SMT) method.

Accordingly, a length of the socket pin can be decreased as compared with a conventional socket pin pass-through method, thereby reducing alignment precision deterioration due to bending of the socket pin or the like during insertion of the socket pin into a PTH of a conventional socket pin, and by preventing short circuits between soldering portions of the socket pins, connection defects or lifting inside the PTH, stripping, and fine cracks, productivity, quality, and reliability can be improved and manufacturing cost can be reduced.

Further, by electrically connecting upper and lower layers of the multilayer PCB by fine pillars in a pillar form in place of a PTH formed in a hole form, a heat dissipation effect can be enhanced.

What is claimed is:

1. A method of manufacturing a multilayer printed circuit board (PCB) for semiconductor testing, comprising:
an operation (a) of preparing a copper clad laminate (CCL) plate of which copper foil layers serving as dummy layers are formed on both surfaces of a core layer;
an operation (b) of forming a fine pad to be used for a fine pillar for replacing a plated through hole (PTH) in the CCL plate;
an operation (c) of, in a state in which copper foils are laminated on upper and lower layers of the CCL plate with prepreg interposed therebetween, etching the copper foils to reduce a thickness thereof and then forming a fine hole;
an operation (d) of forming chemical copper on the copper foils of an intermediate product subjected to the operation (c);
an operation (e) of forming electrolytic copper in a state in which a photo resist image is formed using a dry film and forming the fine pillar in the fine hole during the forming of the electrolytic copper;
an operation (f) of forming a circuit pattern by removing the chemical copper and the remaining portions of the copper foils by etching after stripping the dry film; and
an operation (g) of repeatedly performing the operations (c) to (f) until all layers are completely formed.

2. The method of claim 1, wherein the fine pad formed in the operation (b) is formed by forming the fine hole in the CCL plate, copper-plating a wall surface of the fine hole, filling the copper-plated fine hole with a filler of a resin material, and then performing copper plating.

3. The method of claim 2, wherein the number of dummy layers is two or more.

4. The method of claim 3, wherein a thickness of a core of the dummy layer is adjusted to be compatible with an existing multilayer PCB.

5. The method of claim 4, wherein the multilayer PCB is a multilayer PCB for semiconductor package testing.

6. The method of claim 5, wherein the multilayer PCB is a PCB for a device-under-test (DUT) board or a PCB for a main board.

7. A printed circuit board (PCB) for semiconductor testing manufactured by the method of claim 1.

8. A semiconductor test socket assembly comprising:
the PCB for semiconductor testing manufactured by the method of claim 1; and
a test socket including socket pins soldered in a state in which each socket pint is in surface contact with a corresponding one of a plurality of fine pillars exposed on an uppermost layer of the PCB for semiconductor testing and a plurality of dummy pins supported by the PCB for semiconductor testing by vertically passing through the PCB for semiconductor testing.

9. A semiconductor test socket comprising:
socket pins soldered in a state in which each socket pint is in surface contact with a corresponding one of a plurality of fine pillars exposed on an uppermost layer of the PCB for semiconductor testing manufactured by the method of claim 1; and
a plurality of dummy pins supported by the PCB for semiconductor testing by vertically passing through the PCB for semiconductor testing.
